(19) United States
(12) Patent Application Publication
(10) Pub. No.: US 2025/0240069 A1
(43) Pub. Date: Jul. 24, 2025

(54) TIME-INTERLEAVED TRANSCEIVER ARCHITECTURE

(71) Applicant: ARIZONA BOARD OF REGENTS ON BEHALF OF ARIZONA STATE UNIVERSITY, Scottsdale, AZ (US)

(72) Inventor: Saeed Zeinolabedinzadeh, Chandler, AZ (US)

(73) Assignee: ARIZONA BOARD OF REGENTS ON BEHALF OF ARIZONA STATE UNIVERSITY, Scottsdale, AZ (US)

(21) Appl. No.: 19/027,248

(22) Filed: Jan. 17, 2025

Related U.S. Application Data
(60) Provisional application No. 63/623,044, filed on Jan. 19, 2024.

(51) Int. Cl. H04B 7/06; H03F 3/04; H03K 5/00; H03K 5/1252; H03M 1/12

(52) U.S. Cl. CPC H04B 7/0617; H03K 5/1252; H03F 3/04; H03F 2200/294; H03K 2005/00078; H03M 1/12

(57) ABSTRACT

A system and method for digitizing signals from a plurality of channels in parallel, using a time interleaved and beam-forming receiver, such as a phased array, applying appropriate delays, and performing the digitization using analog-to-digital converters sized based on the reciprocal of the number of channels. The system includes a delay line applying a tunable delay to the received signals before the signals are digitized.

### CROSS REFERENCE TO RELATED APPLICATIONS

This application claims the benefit of U.S. Provisional Patent Application No. 63/623,044, entitled Time-Interleaved Transceiver Architecture, filed on Jan. 19, 2024, the contents of which are hereby incorporated by reference in its entirety.

### TECHNICAL FIELD

The present disclosure relates to receivers co-designed with analog-to-digital converters.

### BACKGROUND

A radio receiver recovers data from a carrier signal and provides amplification and filtration before analog-to-digital conversion, which is the process for digitization for further processing in digital domain. The speed of the data, which is modulated on top of a carrier signal, is a fraction of the carrier frequency. The receiver, therefore, down-converts the modulated signal once received at the antenna to remove the carrier from the data and to bring the frequency of the signal to intermediate frequencies for further amplification in baseband, and for conversion to digital. The circuit that performs these operations from the antenna to the baseband is a radio frequency (RF) front-end. There are various architectures for the implementation of RF front ends. A receiver front-end can combine the operations of amplification and down-conversion with the RF front-end. A direct RF to digital conversion can be accomplished for low frequency applications using, for example, a sigma-delta analog-to-digital converter.

What is needed is a system that reduces the complexity, power consumption, and implementation costs of wideband phased array systems. What are further needed are wideband and reconfigurable RF systems that can support a variety of applications using the same hardware and utilizing programmability and reconfigurability to support the requirements of each application. Designing a wideband system includes the design of wideband circuit components, as well as largely tunable LO signal in a wide frequency range, as well as high-band width and high-sampling rate analog-to-digital converters (ADCs). In addition, the LO routing to phased array elements is costly in terms of power consumption. As a result, there is currently no phased array system that can operate for example from DC-50 GHz at once.

### SUMMARY

Systems and methods in accordance with embodiments of the present disclosure enable high-speed data reception and digitization for wideband data detection and adaptive receiver reconfiguration. The systems and methods enable sampling with direct signal (including RF, wideband, high-speed, and pulsed signals) to digital sampling at carrier frequency, down sampling, and over sampling. Whichever is needed can be configured. The systems and methods are applicable to a class of multiple-input multiple-output (MIMO) receivers, and can be used, for example, but not limited to, for wireless applications. The systems and methods enable direct detection and digitization with high-speed sampling and digitization capability. The cooperating phased array receiver and analog-to-digital converter (ADC) of systems and methods of the present disclosure enable time interleaving without signal distribution/division between the parallel channels of digitizers and avoid bandwidth limitations that accompany signal distribution/division. In addition, systems and methods in accordance with embodiments of the present disclosure remove a high frequency LO signal and LO distribution in a phased array system, thus making the system scalable and power/heat efficient. Systems and methods in accordance with embodiments of the present disclosure enable a receiver to convert signals such as, for example, but not limited to, RF signals directly to digital at high frequencies with wide bandwidth and scalability. The system and method provide improved sampling rate digitization over prior systems and methods. The receiver can be adaptively reconfigured for a variety of application scenarios, and data conversion speed and bandwidth can be increased.

Time interleaving is possible without signal distribution between the parallel channels, and bandwidth limitations that result from signal distribution can be avoided. Thus, a large bandwidth operation becomes feasible for phased array architectures that have been limited by digitization speeds. In addition, the systems and methods are scalable, conserve DC power consumption, and reduce overheating. Direct signal to digital conversion at high frequencies with wide bandwidth and scalability enable the receiver to be adaptively reconfigured for a variety of application scenarios. The data conversion speed and bandwidth can be enhanced by multiple orders of magnitudes depending on the array size, and the reconfigurability of the receiver system is greatly enhanced with performance improvement.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method for receiving and processing signals on a plurality of parallel channels. The method includes receiving the signals, time-interleaving the signals, amplifying the time-interleaved signals, filtering the amplified time-interleaved signals, and digitizing the filtered, time-interleaved signals using time-interleaving among the plurality of parallel channels without signal division and without a local oscillator (LO) signal. Other embodiments of this aspect include corresponding computer systems, apparatus, and computer programs recorded on one or more computer storage devices, each configured to perform the actions of the methods.

Implementations may include one or more of the following features. The method may include applying a delay to the received signals before the signals are digitized. The filtering may include selecting a desired band within a full bandwidth, removing undesired signals outside the desired band when the full bandwidth is not required, and providing an antialiasing operation when needed. The digitizing may include using an analog-to-digital converter having a sampling rate equal to a standard sampling rate/a number of the plurality of parallel channels. The method may include correcting channel mismatches using digital calibration, and/or performing the time-interleaving synchronously with beam-forming, and/or digitally combining and processing data from the plurality of parallel channels. Implementations of the described techniques may include hardware, a method or process, or computer software on a computer-accessible medium.

One general aspect includes a system for receiving and processing signals on a plurality of parallel channels. The system includes a receiver receiving the signals, a timer time-interleaving the signals, a low noise amplifier amplifying the time-interleaved signals, a filter filtering the amplified time-interleaved signals, and an analog-to-digital converter digitizing the filtered, time-interleaved signals using time-interleaving among the plurality of parallel channels without signal division and without a LO signal. Other embodiments of this aspect include corresponding computer systems, apparatus, and computer programs recorded on one or more computer storage devices, each configured to perform the actions of the methods.

Implementations may include one or more of the following features. The system may include a delay line applying a tunable delay to the received signals before the signals are digitized. The filtering may include selecting a desired band within a full bandwidth, removing undesired signals outside the desired band when the full bandwidth is not required, and providing an antialiasing operation when needed. The digitizing may include using the analog-to-digital converter having a power rate equal to a standard sampling rate/a number of the plurality of parallel channels. The system may include a device correcting channel mismatches using digital calibration, and/or a device performing the time-interleaving synchronously with beam-forming, and/or a device digitally combining and processing data from the plurality of parallel channels. Implementations of the described techniques may include hardware, a method or process, or computer software on a computer-accessible medium.

One general aspect includes a circuit for receiving and processing signals on a plurality of parallel channels. The circuit includes a receiver receiving the signals, a timer time-interleaving the signals, a low noise amplifier amplifying the time-interleaved signals, a filter filtering the amplified time-interleaved signals, and an analog-to-digital converter digitizing the filtered, time-interleaved signals using time-interleaving among the plurality of parallel channels without signal division and without a LO signal. Other embodiments of this aspect include corresponding computer systems, apparatus, and computer programs recorded on one or more computer storage devices, each configured to perform the actions of the methods.

Implementations may include one or more of the following features. The circuit may include a delay line applying a tunable delay to the received signals before the signals are digitized. The filtering may include selecting a desired band within a full bandwidth, removing undesired signals outside the desired band when the full bandwidth is not required, and providing an antialiasing operation when needed. The digitizing may include using the analog-to-digital converter having a sampling rate equal to a standard sampling rate/a number of the plurality of parallel channels. The circuit may include a device correcting channel mismatches using digital calibration, and/or a device performing the time-interleaving synchronously with beam-forming. Implementations of the described techniques may include hardware, a method or process, or computer software on a computer-accessible medium.

### BRIEF DESCRIPTION OF THE DRAWINGS

The subject matter of the present disclosure is particularly pointed out and distinctly claimed in the concluding portion of the specification. A more complete understanding of the present disclosure, however, may be obtained by referring to the detailed description and claims when considered in connection with the drawing figures, wherein like numerals denote like elements.

FIG. 1 (PRIOR ART) is a schematic diagram of a phased array system with beamforming at intermediate frequency (IF);

FIG. 2 (PRIOR ART) is a schematic diagram of a phased array system with beamforming at local oscillator (LO);

FIG. 3 (PRIOR ART) is a schematic diagram of a phased array system with beamforming in digital;

FIG. 4 is a circuit diagram of wideband time-interleaved phased array receiver architecture in accordance with embodiments of the present disclosure;

FIGS. 5A and 5B illustrate a 16 channel example of an architecture in accordance with embodiments of the present disclosure;

FIGS. 6A and 6B is a combined illustration of the carrier modulated with the data and time interleaved sampling example using time interleaved phased array in the present disclosure; and

FIG. 7 is a flowchart of a method in accordance with embodiments of the present disclosure.

### DETAILED DESCRIPTION

The detailed description of various embodiments herein makes reference to the accompanying drawings and pictures, which show various embodiments by way of illustration. While these various embodiments are described in sufficient detail to enable those skilled in the art to practice the disclosure, it should be understood that other embodiments may be realized and that logical and mechanical changes may be made without departing from the spirit and scope of the disclosure. Thus, the detailed description herein is presented for purposes of illustration only and not of limitation. For example, the steps recited in any of the method or process descriptions may be executed in any order and are not limited to the order presented. Moreover, any of the functions or steps may be outsourced to or performed by one or more third parties. Furthermore, any reference to singular includes plural embodiments, and any reference to more than one component may include a singular embodiment.

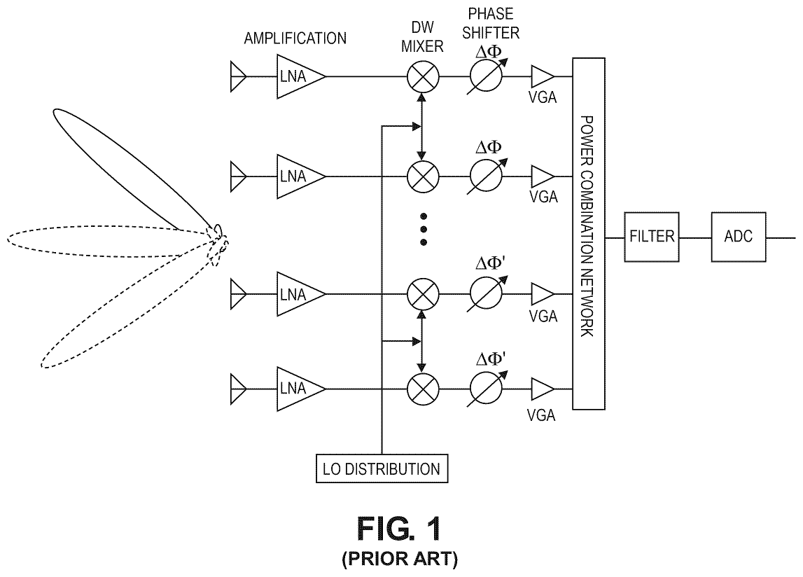

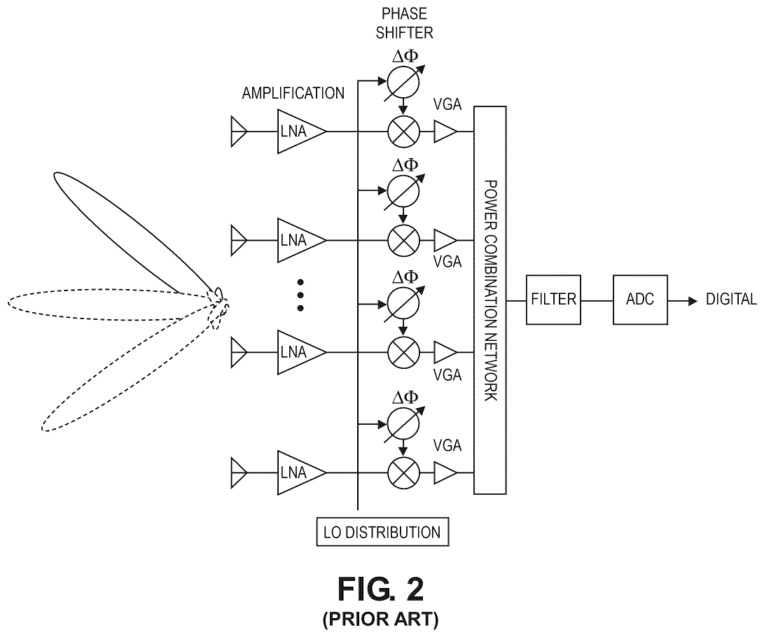

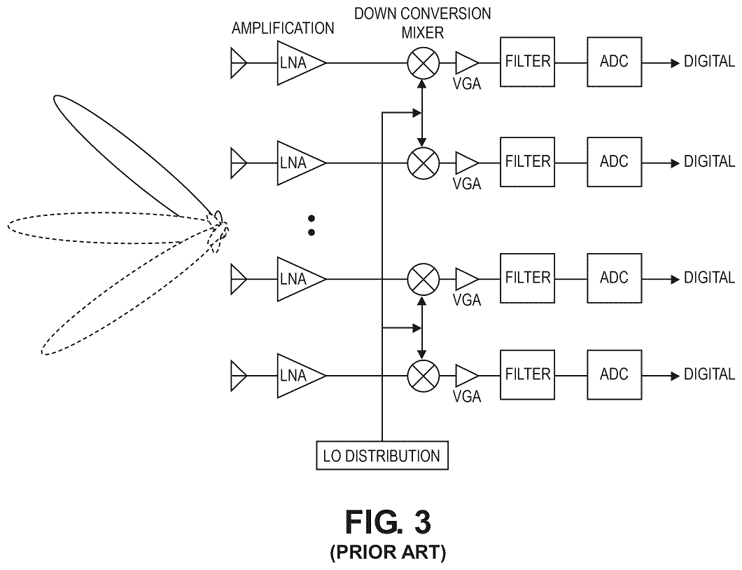

Referring now to FIGS. 1-3 (PRIOR ART), phased array transmitter and receiver circuits are parallel transmit and receive chains that can also be considered as MIMO or multiple-input-single-output (MISO) structures and capable of beamforming and electronic beam steering. FIGS. 1-3 illustrate implementation schemes of phased array systems. Systems and methods in accordance with embodiments of the present disclosure take advantage of the capability of phased array systems in providing parallel receive paths. For example, in a 1000 element phased array receiver system, there are 1000 receivers operating in parallel. In systems and methods in accordance with embodiments of the present disclosure, parallel receiver paths are time-interleaved with other channels to enable direct RF sampling at high frequencies. In other words, the parallel receive channels are co-designed with time-interleaved ADC to create direct RF time interleave sampling. In previous systems, parallel analog-to-digital conversion is part of the ADC and suffers from the bandwidth limitation when the input signal is divided into multiple parallel routes. In the previous systems, the more parallel channels, the lower the bandwidth. Although more channels lower the sampling rate, they can create bandwidth limitation because of signal division at the input of ADC. In systems and methods in accordance with embodiments of the present disclosure, input power division that creates bandwidth limitation is removed and parallel channels of the phased array receiver are directly used. Since the number of parallel channels can be increased without a bandwidth limitation on power division at the input, the interleaving with more channels can enable higher sampling rates. This allows the move to higher frequencies and wider bandwidths. In addition, the present disclosure takes advantage of the tunable delay line in phased array systems for flexible time interleaving.

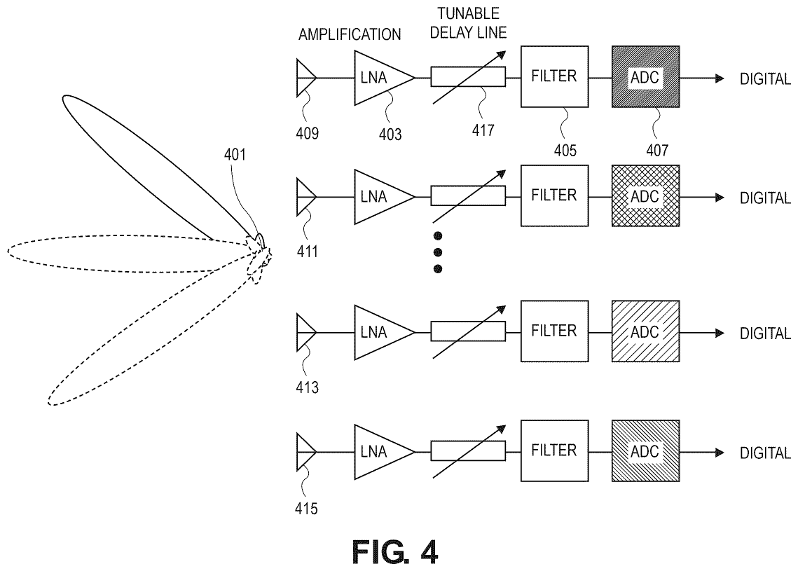

Referring now to FIG. 4, a block diagram of a system in accordance with embodiments of the present disclosure is shown. Incoming received signal 401, is received by an antenna and time-interleaved by tunable delay line 417 with other channels, is amplified by low noise amplifier 403, filtered for selection of a band by filter 405, and digitized by an analog-to-digital converter (ADC) 407. The received signal 401 can include an RF signal or other type of signal. Shown is an example of time interleaving in which channel 409 samples first, then channel 411, then channel 413, then channel 415. There is no signal division, that creates a limit on the bandwidth, between the time interleaving ADC channels 407. The tunable filter 405 allows the selection of a band within the wide bandwidth, and removing the undesired signals on the other parts of the band when the full bandwidth is not required, and to remove the signal aliasing after digitization. For example, for a phased array system that can operate at 10-50 GHz, if a signal at 12-18 GHz is desired, the filter 405 can open the bandwidth to specific frequencies and remove the undesired signals at other frequencies. Sampling occurs directly at RF frequencies, for example, so an antialiasing filter may be unnecessary if the sampling rate is greater than twice the bandwidth of the data, i.e. the Nyquist rate. A local oscillator (LO) signal, and its distribution across the phased array components, may be unnecessary. A similar architecture can be used for the transmitter part and phased array transmitters.

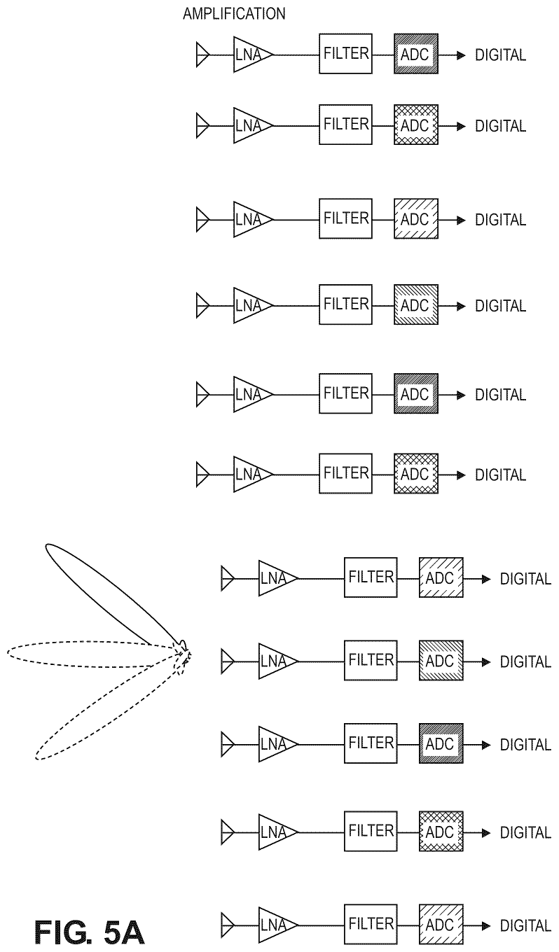

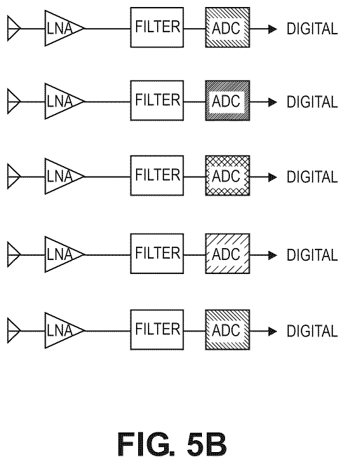

Referring now to FIGS. 5A and 5B, the results of a 16-channel time interleaved phased array receiver along with the direct sampling on modulated data are shown. When sixteen parallel channels of a phased array are used, the sampling rate for the ADC is reduced by sixteen times, enabling the use of low rate and low power ADCs and wideband high-sampling rate digitization. For example, 16 channel and 1 GHz sampling per channel can be used, or utilize 64 channels with 250 MHz (16 GHz/64) sampling rate per channel. The effective-number-of-bits and signal-to-noise-and-distortion ratios in time interleaving can be sensitive to the matching between channels, as well as the accuracy of the time delay between the channels, and digital calibration techniques can be utilized to correct for the channel mismatches. The larger number of channels help to randomize possible errors between channels and help in reducing the undesired spurs as a result of mismatches. Once the signal is digitized, direct signal to digital algorithms can be used to down-convert and extract the data digitally.

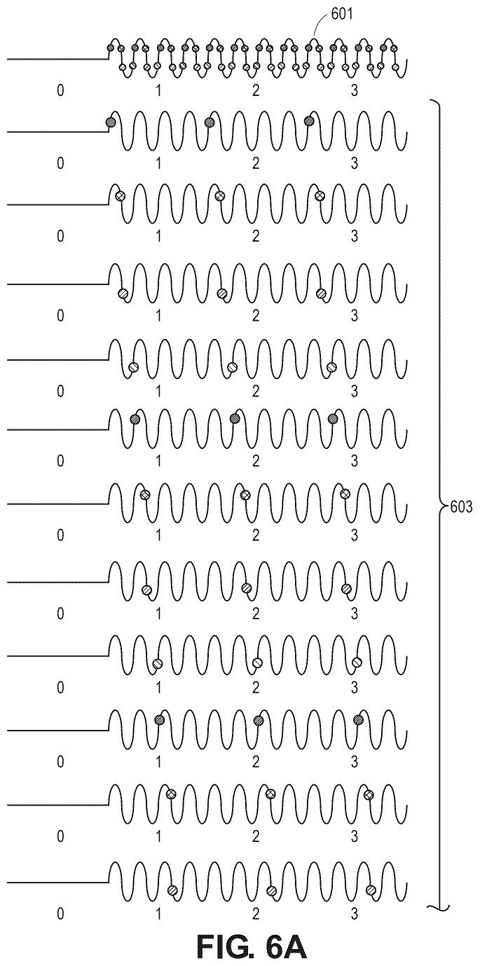

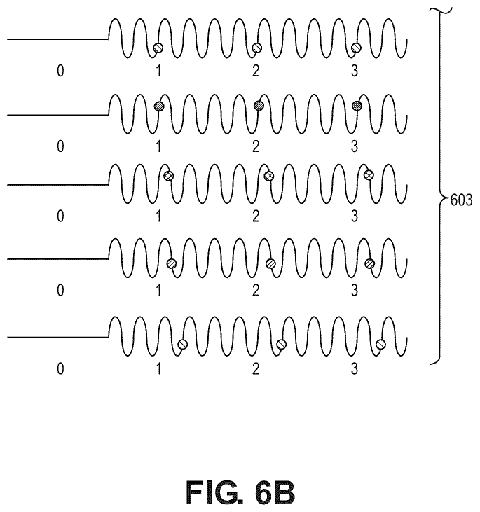

Referring now to FIGS. 6A and 6B, the waveform 601 shows the sampling for a modulated data signal using a 16-channel phased array system for direct digitization, and the graphs 603 with 16 waveforms show the situation when used in a 16-channel time interleaved phased array system.

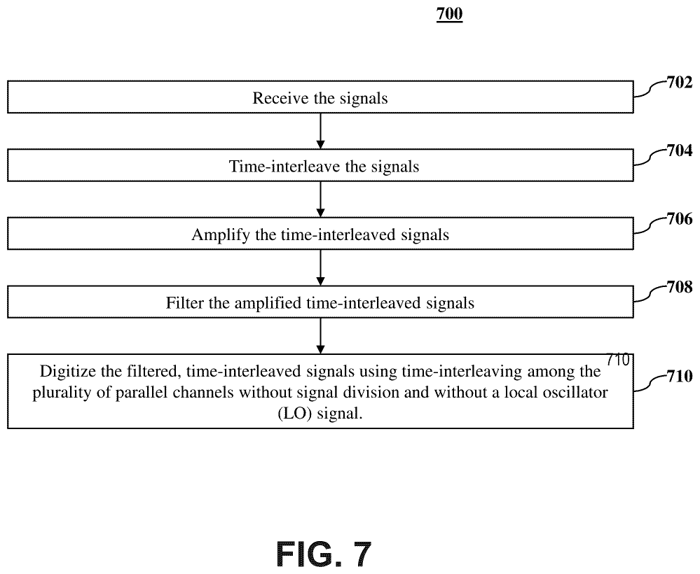

Referring now to FIG. 7, a method 700 for receiving and processing signals on a plurality of parallel channels can include, but is not limited to including, receiving 702 the signals, time-interleaving 704 the signals, amplifying 706 the time-interleaved signals, filtering 708 the amplified time-interleaved signals, and digitizing 710 the filtered, time-interleaved signals using time-interleaving among the plurality of parallel channels without signal division and without a LO signal. In some configurations, the signals include RF signals. In some configurations, the signals include wideband or high-speed signals such as pulses.

As used herein, “electronic communication” means communication of at least a portion of the electronic signals with physical coupling (e.g., “electrical communication” or “electrically coupled”) and/or without physical coupling and via an electromagnetic field (e.g., “inductive communication” or “inductively coupled” or “inductive coupling”). As used herein, “transmit” may include sending at least a portion of the electronic data from one system component to another (e.g., over a network connection). Additionally, as used herein, “data,” “information,” or the like may include encompassing information such as commands, queries, files, messages, data for storage, and the like in digital or any other form.

As used herein, “satisfy,” “meet,” “match,” “associated with”, or similar phrases may include an identical match, a partial match, meeting certain criteria, matching a subset of data, a correlation, satisfying certain criteria, a correspondence, an association, an algorithmic relationship, and/or the like. Similarly, as used herein, “authenticate” or similar terms may include an exact authentication, a partial authentication, authenticating a subset of data, a correspondence, satisfying certain criteria, an association, an algorithmic relationship, and/or the like.

Systems, methods, and computer program products are provided. In the detailed description herein, references to “various embodiments,” “one embodiment,” “an embodiment,” “an example embodiment,” etc. indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure. The scope of the disclosure is accordingly limited by nothing other than the appended claims, in which reference to an element in the singular is not intended to mean “one and only one” unless explicitly so stated, but rather “one or more.” Moreover, where a phrase similar to ‘at least one of A, B, and C’ or ‘at least one of A, B, or C’ is used in the claims or specification, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Although the disclosure includes a method, it is contemplated that it may be embodied as computer program instructions on a tangible computer-readable carrier, such as a magnetic or optical memory or a magnetic or optical disk. All structural, chemical, and functional equivalents to the elements of the above-described various embodiments that are known to those of ordinary skill in the art are expressly incorporated herein by reference and are intended to be encompassed by the present claims. Moreover, it is not necessary for a device or method to address each and every problem sought to be solved by the present disclosure for it to be encompassed by the present claims. Furthermore, no element, component, or method step in the present disclosure is intended to be dedicated to the public regardless of whether the element, component, or method step is explicitly recited in the claims. No claim element is intended to invoke 35 U.S.C. § 112(f) unless the element is expressly recited using the phrase “means for” or “step for”. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In re Nuijten to fall outside the scope of patentable subject matter under 35 U.S.C. § 101.

1. A method for receiving and processing signals on a plurality of parallel channels, the method comprising:
receiving the signals;
time-interleaving the signals;
amplifying the time-interleaved signals;
filtering the amplified time-interleaved signals; and
digitizing the filtered, time-interleaved signals using time-interleaving among the plurality of parallel channels without signal division and without a local oscillator (LO) signal.

2. The method of claim 1, further comprising:
applying a delay to the received signals before the signals are digitized.

3. The method of claim 1, wherein the filtering comprises:
selecting a desired band within a full bandwidth;
removing undesired signals outside the desired band when the full bandwidth is not required; and
providing an antialiasing operation when needed.

4. The method of claim 1, wherein the digitizing comprises:
using an analog-to-digital converter having a sampling rate equal to a standard sampling rate/a number of the plurality of parallel channels.

5. The method of claim 1, further comprising:
correcting channel mismatches using digital calibration.

6. The method of claim 1, further comprising:
performing the time-interleaving synchronously with beam-forming.

7. The method of claim 1, further comprising:
digitally combining and processing data from the plurality of parallel channels.

8. A system for receiving and processing signals on a plurality of parallel channels, the system comprising:
a receiver receiving the signals;
a timer time-interleaving the signals;
a low noise amplifier amplifying the time-interleaved signals;
a filter filtering the amplified time-interleaved signals; and
an analog-to-digital converter digitizing the filtered, time-interleaved signals using time-interleaving among the plurality of parallel channels without signal division and without a local oscillator (LO) signal.

9. The system of claim 8, further comprising:
a delay line applying a tunable delay to the received signals before the signals are digitized.

10. The system of claim 8, wherein the filtering comprises:
selecting a desired band within a full bandwidth;
removing undesired signals outside the desired band when the full bandwidth is not required; and
providing an antialiasing operation when needed.

11. The system of claim 8, wherein the digitizing comprises:
using the analog-to-digital converter having a power rate equal to a standard sampling rate/a number of the plurality of parallel channels.

12. The system of claim 8, further comprising:
a device correcting channel mismatches using digital calibration.

13. The system of claim 8, further comprising:
a device performing the time-interleaving synchronously with beam-forming.

14. The system of claim 8, further comprising:
a device digitally combining and processing data from the plurality of parallel channels.

15. A circuit for receiving and processing signals on a plurality of parallel channels, the circuit comprising:
a receiver receiving the signals;
a timer time-interleaving the signals;
a low noise amplifier amplifying the time-interleaved signals;
a filter filtering the amplified time-interleaved signals; and
an analog-to-digital converter digitizing the filtered, time-interleaved signals using time-interleaving among the plurality of parallel channels without signal division and without a local oscillator (LO) signal.

16. The circuit of claim 15, further comprising:
a delay line applying a tunable delay to the received signals before the signals are digitized.

17. The circuit of claim 15, wherein the filtering comprises:
selecting a desired band within a full bandwidth;
removing undesired signals outside the desired band when the full bandwidth is not required; and
providing an antialiasing operation when needed.

18. The circuit of claim 15, wherein the digitizing comprises:
using the analog-to-digital converter having a sampling rate equal to a standard sampling rate/a number of the plurality of parallel channels.

19. The circuit of claim 15, further comprising:
a device correcting channel mismatches using digital calibration.

20. The circuit of claim 15, further comprising:
a device performing the time-interleaving synchronously with beam-forming.
